(19) United States
(12) Patent Application Publication
(10) Pub. No.: US 2021/0305898 A1
(43) Pub. Date: Sep. 30, 2021

(54) DC-DC Converter variable input high efficiency

(71) Applicant: FRANCESCO VILARDO, FUSCALDO (IT)

(72) Inventor: FRANCESCO VILARDO, FUSCALDO (IT)

(73) Assignee: FRANCESCO VILARDO, FUSCALDO (IT)

(21) Appl. No.: 17/210,546

(22) Filed: Mar. 24, 2021

(30) Foreign Application Priority Data
Mar. 27, 2020 (IT) 102020000015049

(51) Int. Cl. H02M 3/158; G05F 3/18; G01R 19/165; H02P 7/28

(52) U.S. Cl. CPC H02M 3/158; G05F 3/18; H02M 2001/0025; H02P 7/28; G01R 19/16538

(57) ABSTRACT

The invention FIG. 1 is a dc-dc converter with variable unpredictable input voltage in direct current, to output voltage in direct current always stable at fixed value, with high efficiency above ninety-five percent, with very low heat dissipation.

The invention is created for automobile industry to allow the use of capacitor batteries, but it can be used in all electric devices like dc-dc converter step down, also as integrated on chip.

### RELATED APPLICATION

This application claims the benefit of Italian Patent Application No. 102020000015049, filed on 27 Mar. 2020, inventor Francesco Vilardo, all contents of above-identified document are herein incorporated by reference.

About prior state of art of italian patent application No. 102020000015049, the examiner of european patent office writes in its report of research of priority, the relevant documents are U.S. Pat. No. 3,809,975A (1974), JPS52798U (1977), RU2027063C1 (1995), JPS5419579U (1979), US2013234293A1 (2013), US2009196005 (2009).

### SUMMARY OF INVENTION

The invention FIG. 1 is a converter from direct current with higher unpredictable variable voltage to direct current with lower fixed voltage, with very high efficiency, the converter is intended for the automotive industry, but it can also be used in electronic devices, where a dc-dc converter is needed to lowers the voltage with high efficiency; in the automotive industry the invention allows the use of parallel capacitors batteries which are unusable today, because they are at variable voltage according to the well-known graph of the capacitor discharge, then the capacitors batteries decrease voltage when discharging, with the invention an always stable voltage output is obtained with a variable voltage input.

### TECHNICAL FIELD

The field of the technique to which the invention refers, is that of direct current to direct current transformers, called dc-dc converters, they convert a direct current from one voltage to another voltage; my invention belongs to the category of dc-dc converters that convert exclusively from a higher voltage to a lower voltage, called step down.

### BACKGROUND

Due to the pre-existing state of the art, or the state of the art or technological background, there is currently no production and not on the market a dc-dc converter capable of allowing the use of capacitors batteries FIG. 4, or a dc-dc converter that converts an unpredictable variable voltage DC input to an always stable voltage DC output with high efficiency. There are dc-dc transformers in production that convert a stable voltage in input into a variable voltage in output, they are called Transformers, dc-dc converters or stabilized power supplies.

### BRIEF DESCRIPTION OF DRAWINGS

FIG. 1 illustrates the dc-dc converter object of the present invention which transforms the variable voltage 101 in input into a fixed voltage in output. 102 is the generical electric device, 103 is the electronic controller, 108 is the node, 104-105 is the plates capacitor, 107 and 106 are the zener or avalanche diodes.

FIG. 2 illustrates a practical application in the automotive industry, with my invention applied to an electric motor 210 driven by a transistor 212 which functions as an accelerator.

FIG. 3 illustrates the charge graph of a capacitor with the point Vzener where the voltage inside the capacitor (104,105) locks in unstable equilibrium as explained above.

FIG. 4 illustrates an example of a parallel capacitor battery for the automotive industry with only three positive plates 401 and three negative plates 402 separated by dielectric. In practice, the capacitors can be billions. It is necessary to remember that in the electronics industry eight billion transistors resistant to breakdown voltage of tens of Volts can be built on a chip.

### DETAILED DESCRIPTION OF THE INVENTION

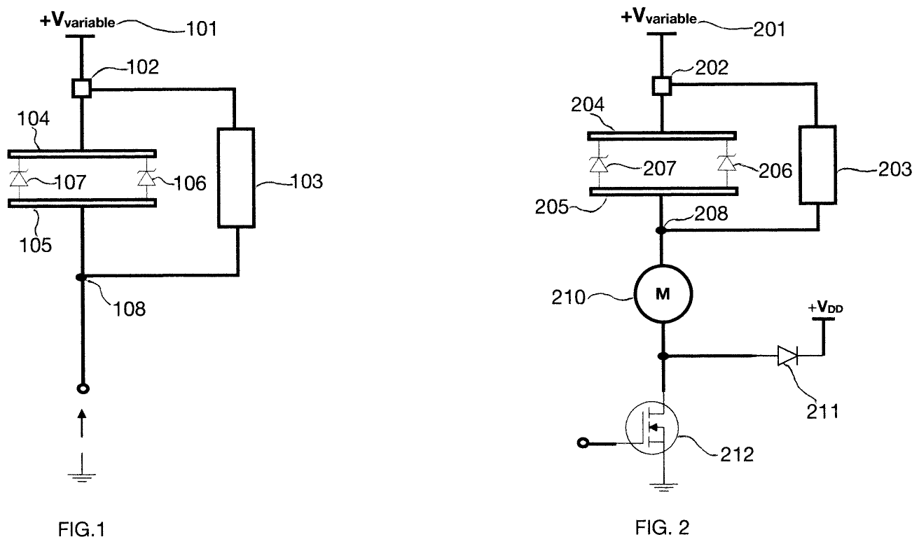

For the exposition of my invention FIG. 1. The technical problem that arises is that at the present state of the art it is impossible to use parallel capacitors batteries in the electric automotive industry, which are economic and long-lasting and very capacious in energy FIG. 4, because the voltage of the battery decreases as the battery discharges due to the well-known graph of the capacitor discharge. My invention FIG. 1 solves the problem, allowing a stable voltage to be output from the battery with a power and torque always stable to the car's electric motor, the high efficiency of the invention allows to use up to ninety percent of the energy contained in the capacitor battery with very little heat dissipation, with efficiency above ninety-five percent.

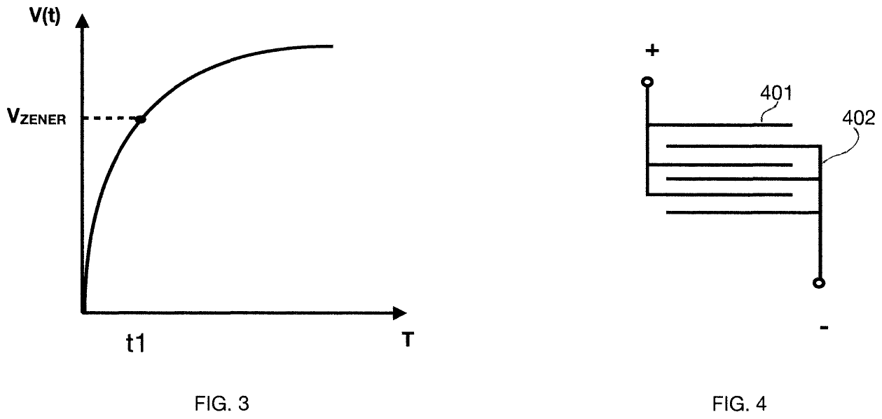

In my invention FIG. 1, the decreasing variable voltage battery 101 supplies current to the plates capacitor (104,105) with generic dielectric between the positive plate 104 and the negative plate 105, the positive plate of the capacitor is charged according to the well-known graph of the charge of the capacitor FIG. 3, when the difference in potential between the two plates of the capacitor reaches Vzener FIG. 3, the two zener or avalanche diodes 107-106 which electrically connect the two capacitor plates, go on conductivity and the current flows between the two capacitor plates 104-105. Due to the voltage stabilizer effect of the two zener diodes, the voltage inside the capacitor 104-105 rises and stops at the voltage Vzener and a direct current with stable voltage is output from the lower plate 105 towards the node 108 equal to Vzener and lower than the voltage +Vvariable 101, the capacitor 104-105 is now conductive because of the zener or avalanche diodes.

An unstable voltage equilibrium is thus obtained inside the capacitor, because according to the physics of the charge of the capacitor whatever it is the input voltage 101, the voltage inside the capacitor starts from zero and increases according to the graph FIG. 3 and can be stopped by a zener or avalanche diode. If the unstable voltage equilibrium inside the capacitor breaks, the capacitor 104-105 goes into saturation (similar to a transistor) and the voltage rises above Vzener, in this case the feedback block 103 built as electronic circuitry with technology WLC or PLC, detects at node 108 a voltage different than Vzener and manages with a pulse the generic electrical device 102 (which can be a transistor) by interrupting or decreasing the current that flow through the electrical device 102 for some microsecond, the capacitor discharges and restarts from zero voltage according to the graph FIG. 3 until it stops again in Vzener with a new equilibrium.

The feedback block 103 (electronic controller) can interrupt the current with the electric device 102 many times per second. When the input voltage 101 drops below Vzener the zener diodes stop conducting, and the converter shuts down. With an output voltage equal to half the maximum input voltage 101 the converter uses ninety percent of the capacitors battery energy FIG. 4 before switching off.

My invention FIG. 1 allows to transform a variable dc current input into a fixed dc current with high efficiency above ninety-five percent, the resistance of the zener diode and of the other components is very low. An automobile capacitor battery FIG. 4 can contain one billion capacitors with present technology.

For the description of a practical implementation of the invention, I refer to the second figure FIG. 2 which is an application to an automotive direct current electric motor 210 for electric cars. The parallel capacitors battery 201 supplies voltage and current, the device above 202 is a generic electrical device which can also be a Mos or Bjt transistor managed by the side block 203 built in WLC or PLC with microprocessor, which compares the node 208 with a reference voltage, and if the block 203 detects a voltage higher than the zener voltage of the two diodes 207-206 interrupts the current for a few microseconds in the device above 202 causing the capacitor plates 204-205 discharge and start charging again, from zero voltage, until the equilibrium at Vzener voltage is again reached as explained previously in the exposition of the invention. Any oscillation of current at the motor 210 or the stop of the motor itself that starts to operate as a generator and sends reverse current, produce the zener voltage of the diodes to be exceeded inside the capacitor 201-205 and the invention stops working, the feedback block 203 prevents the occurrence of this event by intervening with its circuitry on the electrical device 202 which can interrupt or modulate the input current, discharging the capacitor which then regains its equilibrium at the voltage Vzener as explained above. Thanks to my invention, a constant voltage current equal to the zener voltage of the two diodes reaches the DC electric motor 210, the electric motor can operate at constant torque and power because the voltage is constant. The protection diode 211 prevents damage to the NMos transistor 212 which regulates the speed and start and stop of the motor (accelerator pedal) piloted on the Mos gate.

For the novelty and the inventive step of the invention, the invention is not a diode parallel with a capacitor, the invention is a capacitor with one or two or more diodes inside the capacitor and the capacitor connected with an electrical device 102 and a feedback electronic controller with the purpose of working all together as a converter. Not in electronics books nor in web search engines it is possible to find capacitors with diodes inside or a dc-dc converter similar to my invention, it is a new dc-dc converter.

For the industrial applicability of the invention, the invention is intended for the automotive industry of electric cars, where it allows you to use the cheap capacitors batteries that are impossible to use today because there is no electronic device like my invention. However, my invention can also be used in every field of technology where condenser batteries are used. My invention can also be used in electronic devices where a dc-dc converter is needed. The industrial advantage of my invention also is the high conversion efficiency above ninety-five percent with very low heat dissipation.

1. A DC-DC converter from variable DC input voltage to stationary DC output voltage lower than input, comprising:
a variable voltage direct current source;
an electrical device capable of functioning as a switch or modulator for the purpose of interrupt or allow or modulate the current between the source and the upper plate of capacitor, connected with voltage source, capacitor and electronic controller;
a capacitor made of electrically conductive material, made up of a positive plate opposite and parallel and separated by a dielectric of the negative plate, connected with the electrical device;
two zener or avalanche diodes of same zener voltage, which create electrical contact between the two plates of the capacitor when the plates reach a potential difference equal to the zener voltage, and the cathode and anode are electrically connected to the plates;
an electronic controller connected with the electrical device made up of circuitry configured to read the voltage at the node and if the voltage is different from a fixed value, generate an impulse that drives the electrical device by interrupting or allowing or modulating the flow of the current.

2. The converter of claim 1, wherein the electrical device is an electromechanical switch capable of interrupting or allowing the flow of current, driven by the impulse of the controller.

3. The converter of claim 1, wherein the electrical device is a transistor capable of interrupting or allowing or modulating the flow of current, driven by the impulse of controller.

4. The converter of claim 1, wherein there is the presence of a single zener or avalanche diode between the capacitor plates.

5. The converter of claim 1, wherein there is the presence of more than two zener or avalanche diodes between the capacitor plates.

6. A method of self-piloting of the dc-dc converter of claim 1 comprising the steps:
the controller compares the voltage read on the node with a reference voltage equal to voltage wanted at the converter output;
if the voltage read is higher than the reference, the circuitry of the controller generates a pulse that drives the electrical device which interrupts or decreases the flow of current for a period of time, causing discharging of the capacitor.
